(19) United States
(12) Patent Application Publication
(10) Pub. No.: US 2025/0247971 A1
(43) Pub. Date: Jul. 31, 2025

(54) ELECTRONIC DEVICE

(71) Applicant: DENSO CORPORATION, Kariya-city (JP)

(72) Inventor: MIKITO OGUSU, Kariya-city (JP)

(21) Appl. No.: 18/917,052

(22) Filed: Oct. 16, 2024

(30) Foreign Application Priority Data
Jan. 29, 2024 (JP) 2024-010989

(51) Int. Cl. H05K 5/02; H05K 7/20

(52) U.S. Cl. CPC H05K 5/0213; H05K 7/20154

(57) ABSTRACT

An electronic device includes a housing for accommodating a heat generating component, a cover portion that is disposed to cover a cooling surface of the housing from above and forms a flow path of a refrigerant between the cover portion and the cooling surface of the housing, and a fan unit disposed downstream of the flow path for causing the refrigerant to flow through the flow path. The fan unit is provided at a position above and away from the cooling surface of the housing.

### CROSS REFERENCE TO RELATED APPLICATIONS

This application is based on Japanese Application No. 2024-10989 filed on Jan. 29, 2024, the contents of which are incorporated herein by reference.

### TECHNICAL FIELD

The present disclosure relates to an electronic device.

### BACKGROUND ART

Conventionally, electronic devices such as ECUs (Electronic Control Units) mounted on vehicles and the like are known.

### SUMMARY

The present disclosure has an object to provide an electronic device that can suppress the occurrence of malfunctions in a fan unit and improve reliability.

An electronic device according to one embodiment includes a housing for accommodating a heat generating component, a cover portion that is disposed to cover a cooling surface of the housing from above and forms a flow path of a refrigerant between the cover portion and the cooling surface of the housing, and a fan unit disposed downstream of the flow path for causing the refrigerant to flow through the flow path. The fan unit is provided at a position above and away from the cooling surface of the housing.

### BRIEF DESCRIPTION OF THE DRAWINGS

FIG. 1 is a perspective view illustrating an example of a configuration of an electronic device according to a first embodiment;

FIG. 2 is an exploded perspective view of a cover and a fan unit in the electronic device according to the first embodiment;

FIG. 3 is a cross-sectional view illustrating an example of a configuration of the electronic device according to the first embodiment;

FIG. 4 is a plan view showing a schematic configuration of a housing of the electronic device according to the first embodiment;

FIG. 5 is a diagram showing another example of a ventilation hole formed in a cover portion of the electronic device according to the first embodiment; and

FIG. 6 is a perspective view illustrating an example of an inclined portion provided on the housing of the electronic device according to a second embodiment.

### DETAILED DESCRIPTION

In an assumable example, electronic devices such as ECUs (Electronic Control Units) mounted on vehicles and the like are known. The electronic device includes a housing that houses a board and has a number of fins erected on an outside of a surface facing the housed board, and a cooling fan that is provided on the housing, on the outside of the surface facing the housed board, and blows air onto the number of fins. A flow path is formed between the number of fins, and the cooling fan blows air into an inlet of the flow path.

Incidentally, in the conventional configuration, a configuration is adopted in which air is sucked in from above the cooling fan and blown toward the fins. The air drawn into a fan unit such as a cooling fan may contain foreign matter such as sand and dust. In this case, when a foreign matter enters the air intake of the fan unit, the foreign matter may come into contact with a blade portion, such as an impeller, that constitutes part of the fan unit, which may cause problems such as failure of the fan unit or abnormal noise.

For example, it is conceivable to provide a filter for the fan unit to prevent the intrusion of foreign matter, but this raises concerns about problems such as clogging of the filter and a decrease in an intake performance of the fan unit. Thus, there is room for improvement in terms of preventing malfunctions of the fan unit caused by the intrusion of foreign matter.

The present disclosure has been made in consideration of the above-mentioned problems, and has an object to provide an electronic device that can suppress the occurrence of malfunctions in the fan unit and improve reliability.

In order to achieve the above object, an electronic device according to one embodiment includes a housing for accommodating a heat generating component, a cover portion that is disposed to cover a cooling surface of the housing from above and forms a flow path of a refrigerant between the cover portion and the cooling surface of the housing, and a fan unit disposed downstream of the flow path for causing the refrigerant to flow through the flow path. The fan unit is provided at a position above and away from the cooling surface of the housing.

This makes it possible to prevent foreign matter that has entered the flow path from coming into contact with the fan unit. Therefore, the occurrence of malfunctions in the fan unit can be suppressed. This improves the reliability of the electronic device.

Hereinafter, multiple embodiments will be described with reference to the drawings. In the embodiments, substantially the same components are denoted by the same reference numerals, and the description thereof will be omitted.

### First Embodiment

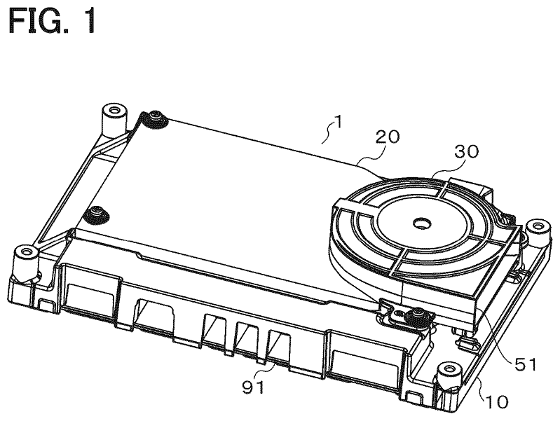

A first embodiment is described with reference to FIGS. 1 to 5.

The electronic device 1 shown in FIG. 1 is configured as an ECU mounted on a vehicle, for example. The ECU is an abbreviation for electronic control unit. The electronic device 1 is provided, for example, below a seat of the vehicle. The electronic device 1 includes a housing 10, a cover portion 20, and a fan unit 30.

The housing 10 is formed into a substantially rectangular box shape, for example, from a combination of synthetic resin and metal. The housing 10 accommodates a substrate 91 such as a printed wiring board inside. Electronic components including switching elements such as IGBTs and MOSFETs are mounted on the substrate 91. The substrate 91 corresponds to a heat-generating component.

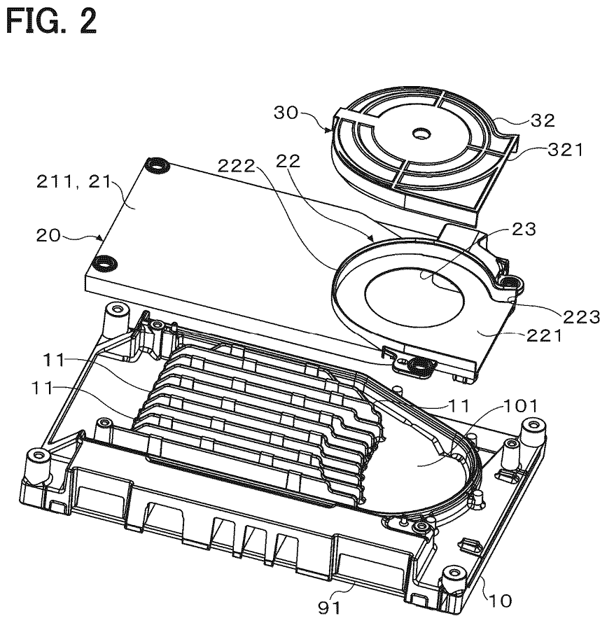

As shown in FIG. 2 and other figures, the housing 10 has a plurality of fins 11. The multiple fins 11 are provided rising upward from a top surface 101 of the housing 10 outwardly, upward in this figure, and extend along a longitudinal direction of the housing 10. The multiple fins 11 are arranged approximately parallel to one another at predetermined intervals in a width direction of the housing 10. In this case, the housing 10 is a die-cast housing in which a heat sink is formed by the multiple fins 11. The top surface 101 of the housing 10 functions as a cooling surface. In FIG. 2 and other figures, in order to make the drawings easier to understand, reference numerals are given to only some of the multiple fins 11, and reference numerals to the other fins 11 are omitted.

The cover portion 20 is formed in a generally container-like shape as a whole, and is disposed so as to cover a portion of the top surface 101 of the housing 10 from above. The cover portion 20 is removably attached to the housing 10 by, for example, screw fastening. As shown in FIG. 2, the cover portion 20 has a cover main body 21, a storage section 22, and a ventilation hole 23. The cover main body 21 constitutes a main body of the cover portion 20. The cover main body 21 has a wall surface 211 having a substantially rectangular shape. The storage section 22 is located on the other end side of the cover portion 20 in the longitudinal direction. The storage section 22 is integrally formed and connected to the wall surface 211. The longitudinal direction of the cover portion 20 and the longitudinal direction of the housing 10 coincide with each other. Further, the width direction of the cover portion 20 and the width direction of the housing 10 coincide with each other.

The storage section 22 has an internal space defined by a bottom wall 221 and a side wall 222. The bottom wall 221 forms a bottom surface of the storage section 22. The side wall 222 is formed rising upward from the bottom wall 221. The side wall 222 extends, for example, in a generally circular shape as a whole. The storage section 22 has a storage section opening 223. The storage section opening 223 is located at the other end of the cover portion 20 in the longitudinal direction, and communicates the inside and outside of the storage section 22. The storage section opening 223 is formed in a substantially rectangular shape. The ventilation hole 23 is formed penetrating the bottom wall 221 of the storage section 22 in the thickness direction. The ventilation hole 23 communicates between the inside and the outside of the housing 10. The ventilation hole 23 is formed, for example, in a circular shape. The shape of the ventilation hole 23 is not limited to a circle and may be other shapes such as an ellipse or a rectangle.

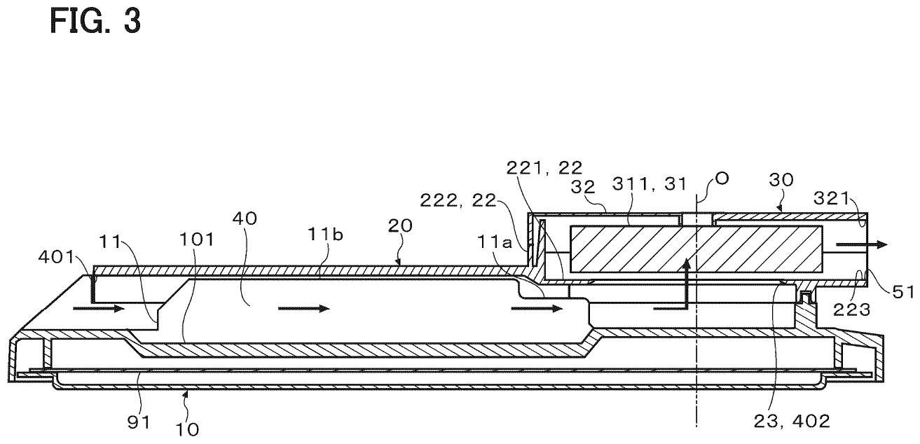

As shown in FIG. 3, the cover portion 20 covers the multiple fins 11 from above. A predetermined gap is formed between the cover portion 20 and the upper ends of the fins 11. The cover portion 20 forms the flow path 40 between itself and the top surface 101 of the housing 10, through which a refrigerant (in this case, air) can pass. In other words, the flow path 40 is provided inside the electronic device 1. In this case, the top surface 101 of the housing 10 constitutes a bottom surface of the flow path 40. The cover portion 20 constitutes an upper surface of the flow path 40.

An inlet 401 of the flow path 40 is formed between the top surface 101 of the housing 10 and one end of the cover portion 20. An outlet 402 of the flow path 40 is constructed by the ventilation hole 23 of the cover portion 20. That is, the ventilation hole 23 communicates the inside and outside of the flow path 40. A direction in which air flows in the flow path 40 coincides with the longitudinal direction of the housing 10 and the cover portion 20. The multiple fins 11 extend along the direction in which air flows in the flow path 40.

The fan unit 30 is positioned downstream of the flow path 40. The fan unit 30 has a function of causing air to flow through the flow path 40. As shown in FIGS. 1 and 2, the fan unit 30 is provided on the upper part of the cover portion 20. In other words, the fan unit 30 is provided at a position above and away from the top surface 101 of the housing 10. In the present embodiment, the air that has flowed through the flow path 40 flows into the fan unit 30 via the ventilation hole 23 of the cover portion 20, as indicated by the black arrow in FIG. 3.

The fan unit 30 includes a fan 31 and a fan case 32. The fan 31 is, for example, a blower-type centrifugal fan. The fan 31 includes an impeller 311. The impeller 311 is connected to a motor (not shown) and is rotated by the motor. The rotation axis of the impeller 311 is oriented, for example, vertically.

The impeller 311 is accommodated in the storage section 22. An outer shape of the storage section 22 corresponds to the outer shape of the impeller 311. As shown in FIG. 3, the impeller 311 is positioned to face the ventilation hole 23 from above. The outer periphery of the impeller 311 is located outside the outer edge of the ventilation hole 23. In other words, the ventilation hole 23 is located inside the outer periphery of the impeller 311. In other words, the ventilation hole 23 is formed in a shape smaller than the outer shape of the impeller 311. Further, the ventilation hole 23 is positioned so as to overlap the center O of the impeller 311 (in this case, the rotation axis) in a plan view. In the present embodiment, the center of the ventilation hole 23 coincides with the center O of the impeller 311.

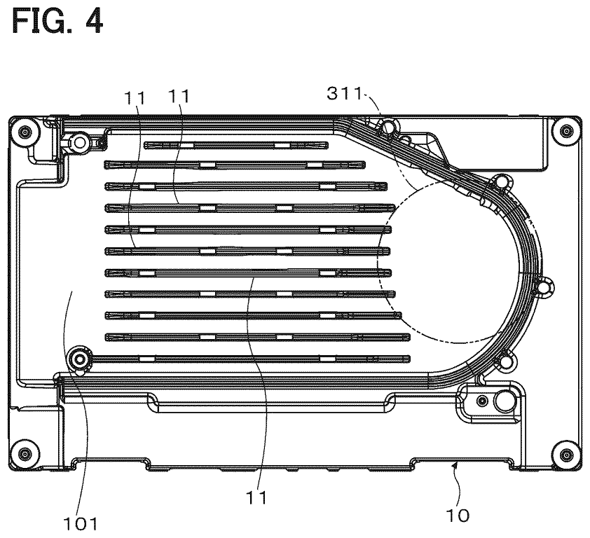

In the present embodiment, as shown in FIG. 4, a portion of the fin 11 is positioned so as to overlap the impeller 311 in the plan view. In this case, the upper ends 11a of a part of the fins 11 are located lower than the upper ends 11b of other part of the fins 11, as shown in FIG. 3. The upper end 11a constitutes the upper end of the fin 11 on the downstream side, while the upper end 11b constitutes the upper end of the fin 11 on the upstream side. In other words, the height dimension of the fins 11 is set smaller on the downstream side than on the upstream side.

The fan case 32 is formed in a generally container shape with one side open. The fan case 32, together with the storage section 22, houses the impeller 311 therein. The impeller 311 is fixed to the fan case 32. The fan case 32 is detachably attached to the side wall 222 of the storage section 22 by, for example, snap fitting. In this case, the outer shape of the fan case 32 is configured to be substantially the same as the outer shape of the storage section 22.

As shown in FIGS. 2 and 3, a case opening 321 is formed at an end of the fan case 32. The case opening 321 is formed in a substantially rectangular shape, and has substantially the same opening width as the storage section opening 223. In a state where the fan case 32 is attached to the storage section 22, the case opening 321 is aligned vertically with the storage section opening 223 to form an exhaust port 51. The exhaust port 51 is configured to discharge the air that has flowed through the flow path 40 and into the fan unit 30 through the ventilation hole 23 to the outside of the fan unit 30.

According to the embodiment described above, the electronic device 1 includes the housing 10, the cover portion 20, and the fan unit 30. The housing 10 accommodates the substrate 91. The cover portion 20 is disposed so as to cover the top surface 101 of the housing 10 from above, and forms the air flow path 40 between itself and the top surface 101 of the housing 10. The fan unit 30 is disposed downstream of the flow path 40 and serves to force air through the flow path 40. The fan unit 30 is provided at a position above and away from the top surface 101 of the housing 10. This makes it possible to prevent foreign matter that has entered the flow path 40 from coming into contact with the fan unit 30. Therefore, the occurrence of malfunctions in the fan unit 30 can be suppressed. As a result, the reliability of the electronic device 1 can be improved.

The cover portion 20 is formed with the ventilation hole 23 that communicates between the inside and the outside of the flow path 40. The fan unit 30 has the impeller 311 that faces the ventilation hole 23 from above. The ventilation hole 23 is located inside the outer periphery of the impeller 311.

According to this configuration, when the foreign matter that has entered the flow path 40 flows out of the flow path 40 through the ventilation hole 23 of the cover portion 20, the foreign matter can be prevented from coming into contact with the outer periphery of the impeller 311. This makes it possible to suppress the occurrence of malfunctions such as breakdowns and abnormal noises of the impeller 311. Therefore, the occurrence of malfunctions in the fan unit 30 can be suppressed.

Further, the ventilation hole 23 is positioned so as to overlap the center O of the impeller 311 in the plan view. This makes it possible to efficiently increase the amount of air drawn into the fan unit 30 through the ventilation hole 23. As a result, the reliability of the electronic device 1 can be improved.

The housing 10 has fins 11. The fins 11 are provided on the top surface 101 of the housing 10 and extend along the direction in which air flows in the flow path 40. A part of the fin 11 is positioned so as to overlap with the fan unit 30 in the plan view. This can ensure a longer length of the fins 11 that come into contact with the air within the flow path 40. This improves the heat dissipation performance of the electronic device 1, and therefore the reliability of the electronic device 1 can be further improved.

Further, the upper ends 11a of a part of the fins 11 are located lower than the upper ends 11b of other part of the fins 11. According to this configuration, by reducing the height of the portion of the fins 11 located below the fan unit 30, the fan unit 30 can be provided as low as possible. This makes it possible to reduce the size of the electronic device 1 while suppressing the occurrence of malfunctions in the fan unit 30.

In the above embodiment, the ventilation hole 23 is described as being configured as a single hole, but the configuration of the ventilation hole 23 is not limited to this configuration. Specifically, the ventilation hole 23 can be configured to have a plurality of holes 231 as shown in FIG. 5. The multiple holes 231 communicate the inside and outside of the flow path 40. In this case, in the example of FIG. 5, each of the plurality of holes 231 includes a central hole 231a and peripheral holes 231b. The central hole 231a is positioned so as to overlap with the center O of the impeller 311. A plurality of, for example six, peripheral holes 231b are arranged at predetermined intervals in a concentric circle shape concentric with the central hole 231a. In FIG. 5, in order to make the drawing easier to understand, reference numerals are given to only some of the multiple peripheral holes 231b, and reference numerals for the remaining peripheral holes 231b are omitted.

In this manner, by configuring the ventilation hole 23 to have a plurality of holes 231, the opening area of each hole 231 can be reduced while ensuring the amount of air passing through the ventilation hole 23 as a whole. This makes it difficult for foreign matter to pass through each hole 231. This prevents foreign matter from coming into contact with the impeller 311, thereby preventing malfunctions of the impeller 311, such as breakdowns and abnormal noise.

### Second Embodiment

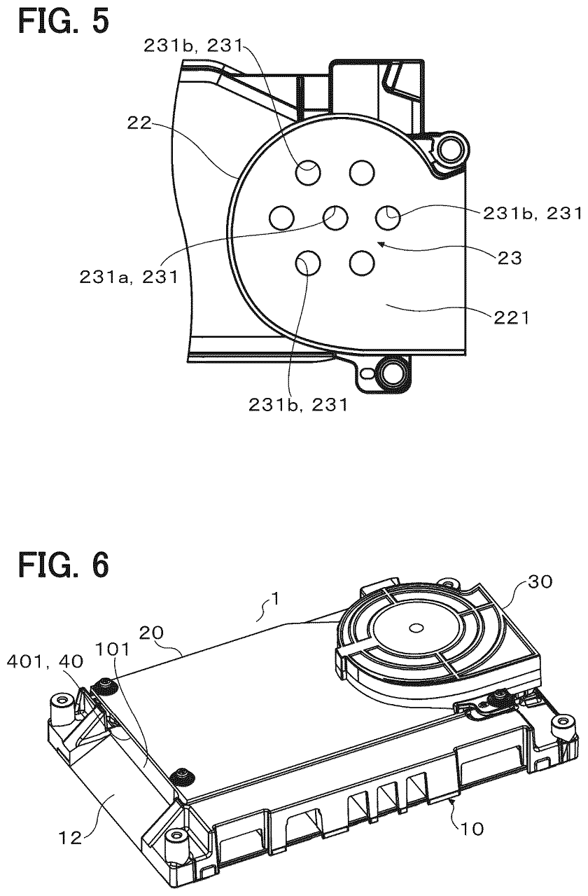

Next, a second embodiment will be described with reference to FIG. 6. In the second embodiment, the structure of the housing 10 is different from that of the first embodiment. Specifically, in the present embodiment, an inclined portion 12 is formed on the top surface 101 of the housing 10. As shown in FIG. 6, the inclined portion 12 is located at one end of the top surface 101 in the longitudinal direction. The inclined portion 12 is formed so as to incline downward from the inside to the outside of the top surface 101. In other words, the inclined portion 12 is inclined downward in the opposite direction to the air flow direction in the flow path 40. The inclined portion 12 is provided at a position connected to the inlet 401 of the flow path 40.

The inclined portion 12 is exposed to the outside of the electronic device 1 when the cover portion 20 is attached to the housing 10. That is, the inclined portion 12 is located outside the flow path 40. In this way, by providing the inclined portion 12 outside the flow path 40, foreign matter such as dust contained in the air flowing into the flow path 40 can be discharged to the outside of the electronic device 1 via the inclined portion 12. Therefore, it is possible to prevent a situation in which foreign matter accumulates near the inlet 401 of the flow path 40 and blocks the inlet 401 of the flow path 40 with the foreign matter.

According to the second embodiment, the same effects as those of the first embodiment can be achieved. Furthermore, the inclined portion 12 makes it easier for foreign matter to fall outside the housing 10. This prevents foreign matter from accumulating near the inlet 401 of the flow path 40 and blocking the flow path 40 with the foreign matter. Therefore, the reliability of the electronic device 1 can be improved.

In addition to the technical features described in the claims, the present disclosure also includes the following technical features.

Feature [1]:

An electronic device includes a housing (10) for accommodating an electric board,
a cover portion (20) that is disposed to cover a cooling surface (101) of the housing from above and forms a flow path (40) of a refrigerant between the cover portion and the cooling surface of the housing, and a fan unit (30) disposed downstream of the flow path for causing the refrigerant to flow through the flow path. The fan unit is provided at a position above and away from the cooling surface of the housing.

Feature [2]: In the electric device according to the feature 1, the cover portion is formed with a ventilation hole (23) that communicates between an inside and an outside of the flow path. The fan unit has an impeller (311) facing the ventilation hole from above. The ventilation hole is located inside an outer periphery of the impeller.

Feature [3]:

In the communication device according to the feature [1], the ventilation hole is positioned so as to overlap a center O of the impeller 311 in a plan view.

Feature [4]:

In the electronic device according to any one of the features [1] to [3], the ventilation hole has a plurality of holes (231) communicating between an inside and an outside of the flow path.

Feature [5]: In the electric device according to any one of the features [1] to [4], the housing has a fin (11) provided on the cooling surface of the housing and extending along a flow direction of the refrigerant in the flow path. A part of the fin is positioned so as to overlap with the fan unit in the plan view.

Feature [6]:

In the electronic device according to the feature [5], an upper end (11a) of a part of the fins is located lower than an upper end (11b) of other part of the fin.

Feature [7]:

In the electronic device according to any one of the features [1] to [6], the flow path has an inlet (401) formed between the cooling surface of the housing and the cover portion. The housing further includes an inclined portion (12) provided at a position connected to the inlet and formed to incline downward in a direction opposite to the flow direction of the refrigerant in the flow path.

The above embodiments can be combined with each other. Also, only the characteristic features of each embodiment may be extracted and combined.

Although the present disclosure has been described in accordance with the embodiments, it is understood that the present disclosure is not limited to such embodiments or structures. The present disclosure encompasses various modifications and variations within the scope of equivalents. In addition, while the various combinations and configurations, which are preferred, other combinations and configurations, including more, less or only a single element, are also within the spirit and scope of the present disclosure.

What is claimed is:

1. An electronic device, comprising:
a housing for accommodating an electric board;
a cover portion that is disposed to cover a cooling surface of the housing from above and forms a flow path of a refrigerant between the cover portion and the cooling surface of the housing; and
a fan unit disposed downstream of the flow path for causing the refrigerant to flow through the flow path, wherein
the fan unit is provided at a position above and away from the cooling surface of the housing.

2. The electronic device according to claim 1, wherein
the cover portion is formed with a ventilation hole that communicates between an inside and an outside of the flow path,
the fan unit has an impeller facing the ventilation hole from above, and
the ventilation hole is located inside an outer periphery of the impeller.

3. The electronic device according to claim 2, wherein
the ventilation hole is positioned so as to overlap a center of the impeller in a plan view.

4. The electronic device according to claim 1, wherein
a ventilation hole has a plurality of holes communicating between an inside and an outside of the flow path.

5. The electronic device according to claim 1, wherein
the housing has a fin provided on the cooling surface of the housing and extending along a flow direction of the refrigerant in the flow path, and
a part of the fin is positioned so as to overlap with the fan unit in a plan view.

6. The electronic device according to claim 5, wherein
an upper end of a part of the fin is located lower than an upper end of other part of the fin.

7. The electronic device according to claim 1, wherein
the flow path has an inlet formed between the cooling surface of the housing and the cover portion, and
the housing includes an inclined portion provided at a position connected to the inlet and formed to incline downward in a direction opposite to a flow direction of the refrigerant in the flow path.
